(19) United States
(12) Patent Application Publication
(10) Pub. No.: US 2026/0268998 A1
(43) Pub. Date: Sep. 10, 2026

(54) IN-SYSTEM ON-CHIP MEMORY REPAIR FOR SAFETY CRITICAL APPLICATIONS AND AUTOMOTIVE DESIGN

(71) Applicant: QUALCOMM Incorporated, San Diego, CA (US)

(72) Inventors: Rajesh Kumar Tiwari, Bangalore (IN); Mohammed Zuber P Malek, Bengaluru (IN); Anurag Agarwal, Jaipur (IN); Srinivas Patil, Austin, TX (US); Nir Maor, San Diego, CA (US)

(21) Appl. No.: 19/072,762

(22) Filed: Mar. 6, 2025

(51) Int. Cl. G11C 29/44; B60R 16/023

(52) U.S. Cl. CPC G11C 29/4401; B60R 16/0232

(57) ABSTRACT

This disclosure provides systems, methods, and devices for memory systems that support an in-system and on-chip repair of a memory of an automotive embedded system of a vehicle. In a first aspect, a method includes: determining, by a processor, for each unit of a memory of a vehicle, whether the unit passes or fails a memory function test; determining, by the processor, whether one or more units of the memory that fail the retention function test are repairable or non-repairable; and adjusting, by the processor and during operation of the vehicle, access to at least one unit of the memory that fails the memory function test and is repairable without fusing any units of the memory. Other aspects and features are also claimed and described.

### TECHNICAL FIELD

Aspects of the present disclosure relate generally to memory systems, and more particularly, to memory repair. Some features may enable and provide improved memory capabilities for repairing itself during operation of the memory.

### INTRODUCTION

Embedded systems, such as those used in automotives and other devices, may include one or several processors to perform various computing functions, such as telephony, vehicle navigation, wireless data access, and camera/video function, etc. A memory system is an important component of the embedded system. The processors may be coupled to the memory system to perform the aforementioned computing functions. For example, the processors may fetch instructions from the memory system to perform the computing functions and/or to store within the memory system temporary data involved in performing these computing functions.

Memory systems may make use of memory cells that are volatile in nature. With technology scales shrinking and embedded systems becoming increasingly more complex in design, memory systems in embedded devices are particularly susceptive to failure due to the dense structure of the memory systems. Any latent or hard errors in the memory can impact the overall silicon life cycle of the memories. The breakdown of a memory system in automotive embedded systems can be particularly hazardous for a vehicle, especially when the vehicle is in operation. As such, memory testing and repair is crucial in the testing process of the embedded system.

### BRIEF SUMMARY OF SOME EXAMPLES

The following summarizes some aspects of the present disclosure to provide a basic understanding of the discussed technology. This summary is not an extensive overview of all contemplated features of the disclosure and is intended neither to identify key or critical elements of all aspects of the disclosure nor to delineate the scope of any or all aspects of the disclosure. Its sole purpose is to present some concepts of one or more aspects of the disclosure in summary form as a prelude to the more detailed description that is presented later.

In some aspects, systems, methods, apparatuses, and devices are disclosed for repairing a memory of an automotive embedded system of a vehicle during operation of the vehicle. The repairing is performed in-system as the repairing is performed by the system itself (e.g., via a processor of the automotive embedded system) using a built-in hardware and software. Furthermore, the memory repair is on-chip as the repairing process does not result in changes to the hardware of the SoC underlying the memory (e.g., the memory repair does not involve fusing any cells, bits, or other units of the memory). The in-system on-chip memory repair may account for previous repairs performed on the memory (e.g., during manufacturing testing) by receiving a memory redundancy register (e.g., having loaded values of previous repairs). The memory repair may further involve running a memory built-in self-test (MBIST) to determine a memory function status (e.g., pass or fail) for a memory function test each unit of the memory. For units failing the memory function test, a built-in redundancy analysis (BIRA) may be run to determine whether and which of those units may be repairable. The in-system on-chip memory repair may then involve adjusting access to at least one unit of the memory that was determined to be fail the memory function test and was determined to be repairable. The adjustment of the access to that faulty unit can then be confirmed (e.g., via another MBIST operation).

Various embodiments of the present disclosure is thus able to salvage the memory by adjusting access to the faulty unit while the vehicle is in operation, thus improving the operation and lifespan of the memory. As the memory repair does not fuse the at least one unit or involve physical alterations of the chip, the memory repair can thus provide a “soft” repair that is implementable by the automotive embedded system while the vehicle is on operation (e.g., in motion), thus obviating the need for manual intervention. Furthermore, the soft repair reduces safety hazards (e.g., for automotives) and lengthens the use of the memory (e.g., until the vehicle is able to reach a safe destination). For example, in some aspects, the presently disclosed memory repair may be performed to “patch-up” the memory while the vehicle is in motion so that a “hard” repair (e.g., involving physically fusing the faulty units of a memory) can performed when the vehicle is able to safely reach a maintenance location.

These aspects may be embodied as a sequence of commands transmitted from a host (e.g., processor of an automotive embedded system of a vehicle) to a memory system. The commands transmitted by the host may include commands to read capabilities from the memory system, set configurations in the memory system, read data at one or more specified addresses from the memory system, and/or write data at one or more specified addresses to the memory system.

An apparatus in accordance with at least one embodiment includes a memory system configured to communicate with a host. The memory system includes a memory array configured to store data. The memory system may include a memory controller configured to provide the data stored in the memory array to the host for further processing by the processor or other components of the host. The memory controller may also be configured to receive data from the host for storage in the memory array. In some embodiments, the memory array may be a plurality of volatile memory cells organized in rows and columns, such as in a dynamic random access memory (DRAM) or static random access memory (SRAM). In other embodiments, the memory array may be a plurality of non-volatile memory cells or a mixture of volatile and non-volatile memory cells.

An apparatus in accordance with at least one other embodiment includes a host device with a memory controller configured to communicate with a memory system to receive data stored in the memory array, store data in the memory array, test memory functions, repair memory functions, and/or validate repair of the memory. The host device may be, for example, vehicle system, such as an automotive embedded system, a user equipment (UE) device such as a cellular phone, a tablet computing device, a personal computer, a server, a smart watch, or an internet of things (IoT) device.

In one aspect of the disclosure, a method for an in-field memory repair includes: determining, by a processor for a memory of a vehicle, whether units of the memory fail a memory function test; determining, by the processor, whether one or more units of the memory that fail the memory function test are repairable; and adjusting, by the processor and during operation of the vehicle, access to at least one unit of the memory that fails the memory function test and is repairable.

In an additional aspect of the disclosure, an apparatus includes at least one processor and a memory coupled to the at least one processor. The memory may be a memory of a vehicle. The at least one processor is configured to determine, for the memory, whether units of the memory fail a memory function test; determine whether one or more units of the memory that fail the memory function test are repairable; and adjust, during operation of the vehicle, access to at least one unit of the memory that fails the memory function test and is repairable. The processor may be a processor, controller, or other logic circuitry in a host. The processor may alternatively be a controller embedded in a memory device.

In an additional aspect of the disclosure, a system for an in-field memory repair in a vehicle is disclosed. The system may include: a memory of the vehicle and at least one processor coupled to the memory. The memory may include a plurality of units and may store processor-readable code. The at least one processor is configured to execute the processor-readable code to cause the at least one processor to perform operations including: determining, for each unit of the memory via a memory built-in self test (MBIST) vector, whether the unit fails a memory function test; determining, via a built-in redundancy analysis (BIRA) vector, based on a memory repair history of the memory, whether one or more units of the memory that fail the memory function test are repairable; adjusting, by enabling a built-in self repair (BISR) vector, access to at least one unit of the memory that fails the memory function test and is repairable without fusing any units of the memory; and confirming, via the MBIST vector, that the access to the at least one unit of the memory is successfully adjusted.

In an additional aspect of the disclosure, an apparatus, such as an automotive embedded system of a vehicle, includes at least one processor and a memory coupled to the at least one processor. The at least one processor is configured to communicate with the memory system through a memory controller coupled to a channel that couples the processor to the memory system. The processor may be a processor, controller, or other logic circuitry in a host.

In an additional aspect of the disclosure, a non-transitory computer-readable medium stores instructions that, when executed by a processor, cause the processor to perform operations described herein regarding aspects of the disclosure.

Memory systems in the present disclosure may be embedded within a processor on a semiconductor die or be part of a different semiconductor die. The memory systems may be of various kinds. For example, the memory may be static random access memory (SRAM), dynamic random access memory (DRAM), magnetic random access memory (MRAM), NAND flash, or NOR flash, etc.

Methods and apparatuses are presented in the present disclosure by way of non-limiting examples of Low-Power Double Data Rate (LPDDR) Synchronous Dynamic Random Access Memory (SDRAM). For example, the LPDDR memory operating in accordance with LPDDR specification promulgated by Joint Electronic Device Engineering Council (JEDEC). One such LPDDR specification may be LPDDR5. Another such LPDDR specification may be LPDDR6.

Other aspects, features, and implementations will become apparent to those of ordinary skill in the art, upon reviewing the following description of specific, exemplary aspects in conjunction with the accompanying figures. While features may be discussed relative to certain aspects and figures below, various aspects may include one or more of the advantageous features discussed herein. In other words, while one or more aspects may be discussed as having certain advantageous features, one or more of such features may also be used in accordance with the various aspects. In similar fashion, while exemplary aspects may be discussed below as device, system, or method aspects, the exemplary aspects may be implemented in various devices, systems, and methods.

The method may be embedded in a computer-readable medium as computer program code comprising instructions that cause a processor to perform the steps of the method. In some embodiments, the processor may be part of a mobile device including a first network adaptor configured to transmit data, such as images or videos in a recording or as streaming data, over a first network connection of a plurality of network connections. The processor may be coupled to the first network adaptor and a memory for storing data to support the processing and communications operations performed by the processor. The network adaptor may support communication over a wireless communications network such as a 5G NR communication network. The processor may cause the transmission of data stored in memory over the wireless communication network.

The foregoing has outlined, rather broadly, the features and technical advantages of examples according to the disclosure in order that the detailed description that follows may be better understood. Additional features and advantages will be described hereinafter. The conception and specific examples disclosed may be readily utilized as a basis for modifying or designing other structures for carrying out the same purposes of the present disclosure. Such equivalent constructions do not depart from the scope of the appended claims. Characteristics of the concepts disclosed herein, both their organization and method of operation, together with associated advantages will be better understood from the following description when considered in connection with the accompanying figures. Each of the figures is provided for the purposes of illustration and description, and not as a definition of the limits of the claims.

While aspects and implementations are described in this application by illustration to some examples, those skilled in the art will understand that additional implementations and use cases may come about in many different arrangements and scenarios. Innovations described herein may be implemented across many differing platform types, devices, systems, shapes, sizes, and packaging arrangements. For example, aspects and/or uses may come about via integrated chip implementations and other non-module-component based devices (e.g., end-user devices, vehicles, communication devices, computing devices, industrial equipment, retail/purchasing devices, medical devices, artificial intelligence (AI)-enabled devices, etc.). While some examples may or may not be specifically directed to use cases or applications, a wide assortment of applicability of described innovations may occur. Implementations may range in spectrum from chip-level or modular components to non-modular, non-chip-level implementations and further to aggregate, distributed, or original equipment manufacturer (OEM) devices or systems incorporating one or more aspects of the described innovations. In some practical settings, devices incorporating described aspects and features may also necessarily include additional components and features for implementation and practice of claimed and described aspects. For example, transmission and reception of wireless signals necessarily includes a number of components for analog and digital purposes (e.g., hardware components including antenna, radio frequency (RF)-chains, power amplifiers, modulators, buffer, processor(s), interleaver, adders/summers, etc.). It is intended that innovations described herein may be practiced in a wide variety of devices, chip-level components, systems, distributed arrangements, end-user devices, etc. of varying sizes, shapes, and constitution.

### BRIEF DESCRIPTION OF THE DRAWINGS

A further understanding of the nature and advantages of the present disclosure may be realized by reference to the following drawings. In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

FIG. 1 shows a block diagram of an example automotive embedded system incorporating a host, a memory, and at least one channel coupling the host and the memory according to one or more aspects of the disclosure.

FIG. 2 shows a block diagram of an example automotive embedded system incorporating a host, a memory, and at least one channel coupling the host and the memory with another implementation of the channel according to one or more aspects of the disclosure.

FIG. 3 shows a block diagram of an example hardware and software components used for the in-system and on-chip memory repair in an automotive embedded system according to one or more aspects of the disclosure.

FIG. 4 shows a flow diagram of an example process for the in-system and on-chip memory repair in the automotive embedded system according to one or more aspects of the disclosure.

FIG. 5 shows a flow diagram of another example process for the in-system and on-chip memory repair in the automotive embedded system according to one or more aspects of the disclosure.

Like reference numbers and designations in the various drawings indicate like elements.

### DETAILED DESCRIPTION

The detailed description set forth below, in connection with the appended drawings, is intended as a description of various configurations and is not intended to limit the scope of the disclosure. Rather, the detailed description includes specific details for the purpose of providing a thorough understanding of the inventive subject matter. It will be apparent to those skilled in the art that these specific details are not required in every case and that, in some instances, well-known structures and components are shown in block diagram form for clarity of presentation.

As previously discussed, latent or hard errors in a memory can impact the overall silicon life cycle of the memory. The breakdown of memory systems in automotive embedded systems of vehicles can be particularly hazardous, especially when the vehicle is in operation. Memory repair typically involves physically replacing defective units (e.g., cells) in the hardware of a memory with a corresponding redundant unit in an irreversible process known as “fusing.” Such memory repair may be performed during the manufacturing process or while the vehicle is in a maintenance facility. When a vehicle is turned on, automotive embedded systems may be checked to ensure their proper and safe operation, in accordance with industry guidelines and specifications (e.g., ISO 26262 standard for automotive safety). A subsequent need for memory repair, especially during the operation, may typically involve ending vehicle operation (e.g., stopping or leading a car to vehicle maintenance facility) to perform the memory repair.

The present disclosure provides systems, apparatus, methods, and computer-readable media that support data processing, including techniques for an in-system and on-chip repair of a memory of an automotive embedded system of a vehicle while the vehicle is in operation. The repairing is performed in-system as the repairing is performed by the automotive embedded system itself (e.g., via a processor) using a built-in hardware and software described herein, thus obviating an immediate need for a vehicle to cease operations when a faulty memory unit is identified. Furthermore, the memory repair is on-chip as the repairing process does not result in changes to the hardware of the SoC underlying the memory (e.g., the memory repair does not involve fusing any cells, bits, or other units of the memory). In various embodiments, the in-system and on-chip memory repair may account for previous repairs performed on the memory (e.g., during manufacturing testing) by receiving a memory redundancy register (e.g., having loaded values of previous repairs), and may include updating the memory redundancy register after performing the in-system and on-chip memory repair. In some embodiments, the memory repair may include a memory built-in self-test (MBIST) to perform a memory function test for each of a plurality of units of the memory to determine a memory function status (e.g., whether a given unit passes or fails the memory function). For units failing the memory function test, a built-in redundancy analysis (BIRA) is performed by the automotive embedded system to determine which of those units may be repairable. For example, despite being determined as failing the test, it is contemplated that some units may not be repairable based on the memory repair techniques described herein (e.g., due to an absence of any redundant fuse bits). The in-system on-chip memory repair may further include adjusting access to at least one unit of the memory. The at least one unit may have been previously determined to fail the memory function test and may have been previously determined to be repairable. The adjustment of the access to that faulty unit can then be confirmed (e.g., via another MBIST operation). In some embodiments, the adjustment may be performed via a built-in self repair (BISR) mechanism using a combination of hardware and software in the automotive embedded system described herein.

Particular implementations of the subject matter described in this disclosure may be implemented to realize one or more of the following potential advantages or benefits. In some aspects, the present disclosure improves the operation and lifespan of the memory by salvaging the memory while the vehicle is still in operation, by adjusting an access to a faulty unit of the memory. As the memory repair does not involve fusing any units or physical alterations of the chip, the memory repair can thus provide a “soft” repair that is implementable by the automotive embedded system while the vehicle is still in operation (e.g., in motion), thus obviating the need for immediate manual intervention. Furthermore, the soft repair reduces safety hazards (e.g., for automotives) and lengthens the use of the memory (e.g., until the vehicle is able to reach a safe destination). For example, in some aspects, the presently disclosed memory repair may be performed to “patch-up” the memory while the vehicle is in motion. The presently disclosed memory repair may also be implemented when a vehicle is powered on. The presently disclosed memory repair may be useful in cases where a “hard” repair (e.g., involving physically fusing the faulty units of a memory) is not possible (e.g., due to slots being unavailable) or inaccessible.

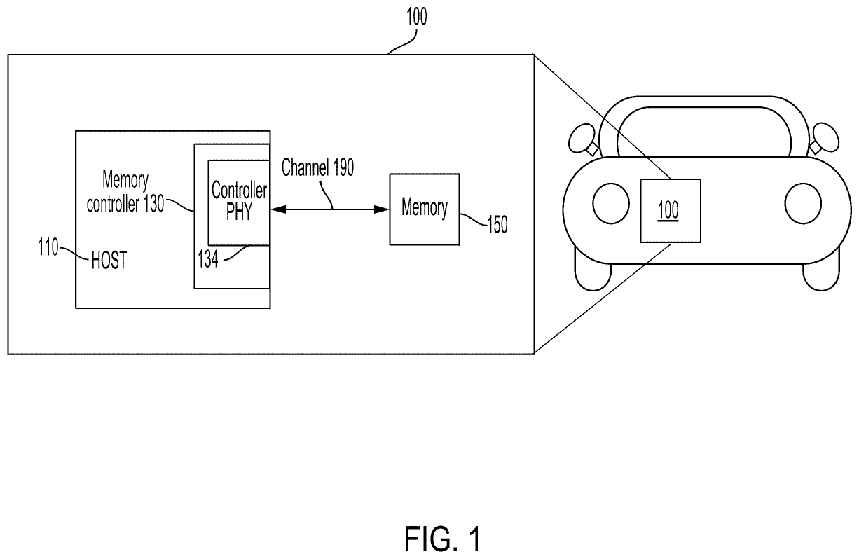

An example memory device that may incorporate aspects of this disclosure, including techniques for in-system and on-chip memory repair in an automotive embedded system, is shown in FIG. 1. FIG. 1 illustrates an apparatus (e.g., automotive embedded system 100) incorporating a host 110, a memory 150, and at least one channel 190 coupling the host 110 and the memory 150. Although the apparatus shown in FIG. 1 is an automotive embedded system 100 of a vehicle, the apparatus may be, in other embodiments, a device among computing systems (e.g., servers, datacenters, desktop computers), mobile computing device (e.g., laptops, cell phones, vehicles, etc.), Internet of Things devices, virtual reality (VR) systems, augmented reality (AR) systems, other automobile systems (e.g., driver assistance systems, autonomous driving systems), medical devices, hospital systems, image capture devices (e.g., stand-alone digital cameras or digital video camcorders, camera-equipped wireless communication device handsets, such as mobile telephones, cellular or satellite radio telephones, personal digital assistants (PDAs), panels or tablets, gaming devices, computing devices such as webcams, video surveillance cameras, or other devices with digital imaging or video capabilities), and/or multimedia systems (e.g., televisions, disc players, streaming devices).

The host 110 may include at least one processor, such as central processing unit (CPU), graphic processing unit (GPU), digital signal processor (DSP), multimedia engine, and/or neural processing unit (NPU). The host 110 may be configured to couple and to communicate to at least one memory 150, via at least one channel 190, in performing memory testing, memory redundancy analysis, memory repair, and other computing functions, such as one of data processing, data communication, graphic display, camera, AR or VR rendering, image processing, neural processing, etc. For example, the at least one memory 150 may store instructions or data for the host to perform the computing functions.

The host 110 may include at least one memory controller 130, which may include at least one controller PHY module 134. Each controller PHY module 134 may be coupled to a respective memory 150 via a respective channel 190. For ease of reference, read and write are referenced from a perspective of the host 110. For example, in a read operation, the host 110 may receive via at least one channel 190 data stored from the memory 150. In a write operation, the host 110 may provide via the at least one channel 190 data to be written into the at least one memory 150 for storage. The memory controller 130 may be configured to control various aspects, such as logic layers, of communications to and from the memory 150. The controller PHY module 134 may be configured to control electrical characteristics (e.g., voltage levels, phase, delays, frequencies, etc.) of signals provided or received on the at least one channel 190, respectively.

In some examples, the at least one memory 150 may be LPDDR DRAM (e.g., LPDDR5, LPDDR6). In some examples, the at least one memory 150 may include different kind of memory devices, such as an LPDDR5, an LPDDR6, a Flash memory, on FPROM, and/or an SRAM. The host 110, the memory 150, and/or the channel 190 may operate according to an LPDDR (e.g., LPDDR5, LPDDR6) specification. In some examples, a channel 190 may include 16 bits of data (e.g., 16 DQs). In some examples, a channel 190 may operate on 32 bits of data (e.g., 32 DQs). In FIG. 1, one channels are shown, however the automotive embedded system 100 may include more or less channels, such as 4, 8, or 16 channels.

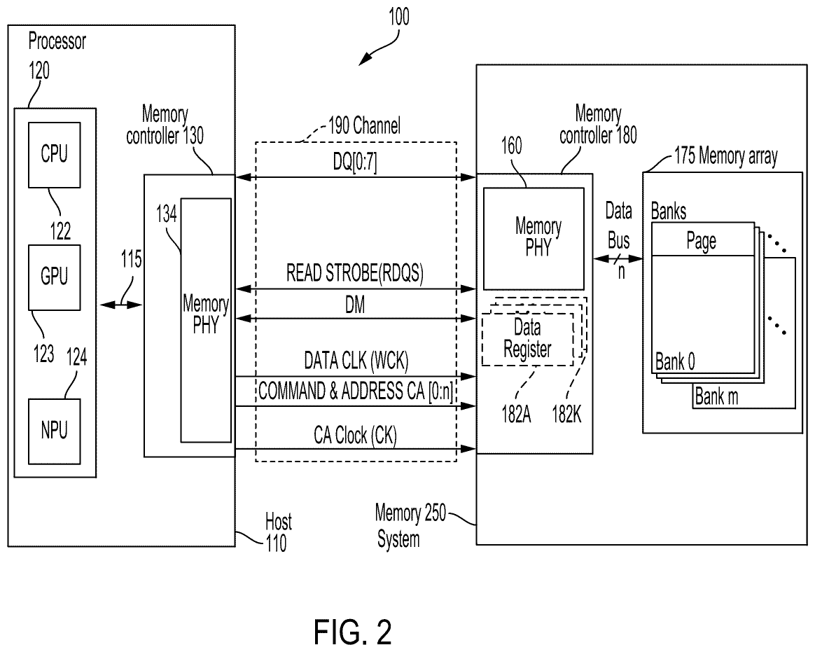

Additional details of an aspect of the embodiment of the automotive embedded system 100 for providing or adjusting access (e.g., during “soft” repair) to one or more aspects of a memory system, such as a memory 150, are shown in FIG. 2. FIG. 2 illustrates a configuration of the host 110, a memory 250, and the channel 190 of FIG. 1. The channel 190 between host 110 and the memory 250 may include a plurality of connections, some of which carry data (e.g., user data or application data) and some of which carry non-data (e.g., addresses and other signaling information). For example, non-data connections in channel 190 may include a data clock (e.g., WCK) used in providing data to the respective memory system 250 and a read data strobe (e.g., RDQS) used in receiving data from the respective memory system 250, on a per byte basis. The channel 190 may further include a data mask (e.g., DM, sometimes referred to as data mask inversion DMI to indicate multiple functions performed by the signal connection) signaling used to mask certain part of data in a write operation. The channel 190 may further include command and address (e.g., CA[0:n]) and associated CA clock to provide commands (e.g., read or write commands) to the memory system 250.

The host 110 may include at least one processor 120, which may include a CPU 122, a GPU 123, and/or an NPU 124. The host 110 may further include a memory controller 130 having a controller PHY module 134. The memory controller 130 may couple to the at least one processor 120 via a bus system 115 in performing the various computing functions. The term “bus system” may provide elements coupled to the “bus system” may exchange information therebetween, directly or indirectly. In different embodiments, the “bus system” may encompass multiple physical connections as well as intervening stages such as buffers, latches, registers, etc. A module may be implemented in hardware, software, or a combination of hardware and software.

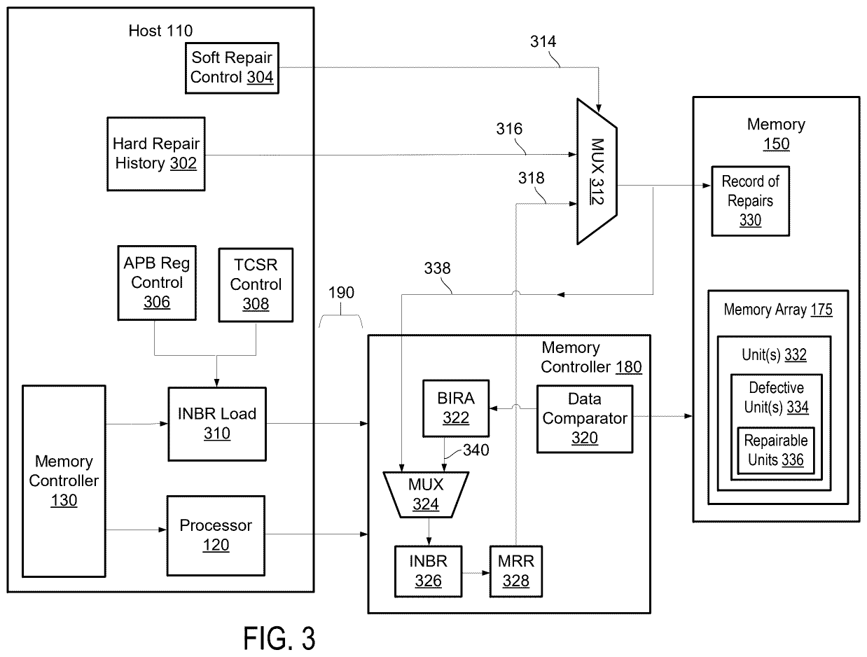

The memory controller 130 may send and/or receive blocks of data to other modules, such as the at least one processor 120 and/or the memory system 250. The memory system 250 may include a memory controller 180 with a memory I/O module 160 (e.g., a PHY layer) configured to control electrical characteristics (e.g., voltage levels, phase, delays, frequencies, etc.) to provide or to receive signals on connections of the channel 190. For example, memory I/O module 160 may be configured to capture (e.g., to sample) data, commands, and addresses from the host 110 via the channel 190 and to output data to the host 110 via the channel 190. Example techniques for communicating on the channel 190 between the memory I/O module 160 and the memory controller 130 are shown in the examples of FIGS. 3-5. The memory controller 180 may also include data registers 182A-K configured to store data in transit between the host 110 and the memory array 175 and/or to store configuration settings or other data.

The memory system 250 may further include a memory array 175, which may include multiple memory cells (e.g., DRAM memory cells, MRAM memory cells, SRAM memory cells, Flash memory cells) that store values. The host 110 may read data stored in the memory array 175 and write data into the memory array 175, via the channel 190 and the memory I/O module 160. The memory array 175 may be divided into a plurality of banks with each bank organized as a plurality of pages.

It is contemplated that, due to the density of the cells in memory array 175, at least one of the cells may become defective. The present disclosure describes techniques for the host 110 of an automotive embedded system of a vehicle to identify and repair the memory system 250 of the automotive embedded system while the vehicle is in operation, without physically altering (e.g., fusing) the memory array 175.

Memory function testing information, memory redundancy analysis, and memory repair information, application or user data may be processed by the processor 120 and the memory controller 130 instructed to store and/or retrieve such data from the memory system 250. For example, memory repair history may be retrieved and/or stored, the results of a memory function test conducted for each of a plurality of cells in the memory array 175 may be retrieved, processed, and/or stored, the results of determining whether a redundant unit of the memory array 175 exists (e.g., conducted via a built in redundancy analysis (BIRA) vector) as well as location of the redundant units may be retrieved, processed, and/or stored. As another example, data may be generated during the execution of an application, such as a spreadsheet program that computes values based on other data. As another example, data may be generated during the execution of an application by receiving user input to, for example, a spreadsheet program. As a further example, data may be generated during the execution of a gaming application, which generates information regarding a representation of a scene rendered by a three-dimensional (3-D) application.

The host 110 is coupled to the memory system 250 via the channel 190, which is illustrated for a byte of data, DQ[0:7]. The channel 190 and signaling between the host 110 and the memory system 250 may be implemented in accordance with the JEDEC DRAM specification (e.g., LPDDR5, LPDDR6). As illustrated, the channel 190 includes signal connections of the DQs, a read data strobe (RDQS), a data mask (DM), a data clock (WCK), command and address (CA[0:n]), and command and address clock (CK). The host 110 may use the read data strobe RDQS to strobe (e.g., to clock) data in a read operation to receive the data on the DQs. The memory system 250 may use the data mask DM to mask certain parts of the data from being written in a write operation. The memory system 250 may use the data clock WCK to sample data on the DQs for a write operation. The memory system 250 may use the command and address clock CK to clock (e.g., to receive) the CAs. A signal connection for each of the signaling may include a pin at the host 110, a pin at the memory system 250, and a conductive trace or traces electrically connecting the pins. The conductive trace or traces may be part of a single integrated circuit (IC) on a silicon chip containing the processor 120 and the memory system 250, may be part of a package on package (PoP) containing the processor 120 and the memory system 250, or may be part of a printed circuit board (PCB) coupled to both the processor 120 and the memory system 250.

The memory system 250 may include a memory I/O module 160 (e.g., a PHY layer) configured to control electrical characteristics (e.g., voltage levels, phase, delays, frequencies, etc.) to provide or to receive signals on the channel 190. For example, memory I/O module 160 may be configured to capture (e.g., to sample) data, commands, and addresses from the host 110 via the channel 190 and to output data to the host 110 via the channel 190. Information transmitted across the channel 190 may be stored in registers in the memory I/O module 160 of the memory system 250 as a temporary or short-term storage location prior to longer-term storage in the memory array 175. An example register may indicate previous repairs performed for any one or more units (e.g., cells, bits, etc.) of the memory array 175.

The memory system 250 may further include a memory array 175, which may include multiple units, such as but not limited to memory cells (e.g., DRAM memory cells) that store information. The host 110 may read data stored in the memory array 175 and write data into the memory array 175 via the channel 190. Moreover, the memory array 175 may be configured to store metadata such as ECCs (e.g., system or array ECCs) associated with the stored data. It is contemplated that the memory array 175 may include, for each of a plurality of units in the memory array 175, a corresponding redundant unit. When a given unit is determined to be defective, the corresponding redundant unit may be used to repair the memory.

Operations according to some embodiments of this disclosure for storing and retrieving information from memory array 175 may be performed by controlling signals on individual lines of the channel 190. Example embodiments of signaling for performing an in-system and on-chip memory repair in an automotive embedded system during operation of a vehicle are shown and described with reference to FIGS. 3-5.

FIG. 3 shows a block diagram of an example hardware and software components used for the in-system and on-chip memory repair in an automotive embedded system according to one or more aspects of the disclosure. In some embodiments, the example hardware and software components may include examples embodiments for, additions to, and/or modifications of the host and the memory systems previously described in relation to FIGS. 1 and 2.

The example hardware and software components may include a host 110 that includes the memory controller 130, the processor 120, and various controls (e.g., soft repair control 304, advanced peripheral bus (APB) register control, and TCSR control 308) and stored or retrieved data (e.g., memory repair history 302 and Internal Built-In Redundance Analysis Register (INBR) load 310). In some embodiments, the host 110 may have previously determined the hard repair history 302 using the at least one channel 190. For example, the host 110 may have previously determined the hard repair history 302 based on characteristics of a field programmable read-only memory (FPROM) of the memory 150 indicating which units or bits of the memory 150 were previously fused and/or otherwise repaired irreversibly. In various embodiments, fusing may refer to an irreversible process where connection to a unit (e.g., a bit, a cell, etc.) of a memory is physically severed (e.g., via a high voltage pulse). In some embodiments, the fusing may further include an irreversible process where a connection to a corresponding redundant unit of the memory is formed (e.g., via an anti-fuse). The hard repair history 302 determined from the FPROM may be stored and/or relayed by the host 110 to a multiplexer 312, as will be described herein.

The INBR load 310 may include a set of (e.g., an array, vector, and/or a matrix of) values to be transmitted to the memory controller 180 (e.g., via channel 190) for entry or input into the Internal BIRA Register (INBR) 326. In some embodiments, the host 110 may initialize the INBR load 310 based on known repair and/or memory function statuses for units of the memory 150 based on the hard repair history 302 (e.g., a value indicating whether a hard repair has occurred for each unit, as determined via the FPROM). For example, if a unit previously underwent a hard repair at the manufacturing stage by fusing the unit, the indication of such repair and/or fusing of the unit may be indicated in the INBR load 310.

In some embodiments, the APB Reg Control 306 is a logic or module that may be configured to allow the host 110 to perform the memory built-in self test (MBIST) on the memory 150, by applying test patterns as a stimulus to test the memory function of each of a plurality of units (e.g., cells, bits, etc.) of the memory 150. In some embodiments, the TCSR control 308 is a logic or module that may be configured to allow the APB Reg control 306 to implement the test patterns on the memory (e.g., via one or more logic gates).

The example hardware and software components may further include the memory 150. As previously discussed, the memory 150 may include one or more memory devices (e.g., DDR, FPROM, SRAM, etc.) for storing data and may be arranged as a memory array (e.g., memory array 175) having a plurality of units 232 (e.g., cells, bits, etc.). The processor 120 may determine (e.g., via a memory built-in self test (MBIST)) that a subset of the units may be defective units 334 based on such units failing a memory function test. Furthermore, the processor 120 may determine (e.g., via the BIRA module 322) that a subset of the defective units 334 may be repairable units 336, as other defective units may not necessarily be repairable.

The example hardware and software components may further include the multiplexer 312. In some embodiments, the multiplexer 312 may receive signal 316 from the host 110 regarding hard repair history 302 of the memory 150 and a signal 318 from the memory controller 180 indicating any soft repairs performed using techniques described herein while a vehicle was in operation.

When a vehicle is powered on or being tested based on system requirements, the example hardware and software components can cause the automotive embedded system to perform the presently disclosed soft repair and memory built-in self test (BIST). Also or alternatively, the soft repair control 304 may enable (e.g., via signal 314) the soft repair to be performed by the automotive embedded system of the vehicle on the memory 150 using techniques described herein, when the vehicle is powered on, being tested, or is otherwise in motion. As previously discussed, a soft repair may refer to a repair of the memory based on identifying at least one defective unit in the memory where the repair does not involve fusing (or otherwise physically irreversibly altering) any units of the memory. In some embodiments, the soft repair may include adjusting access to at least one unit of the memory that is determined to be defective, for example, by denying access to the defective unit and causing a processor or memory controller to access a non-defective unit of the memory instead. The soft repair may be distinguishable from the hardware in that access may be denied to the defective unit in the software based on machine readable commands, without physically severing the physical link to the defective unit. If the soft repair control 304 is toggled to enable the soft repair to occur, the multiplexer 312 may thus receive, in addition to signal 316 indicating any previously performed hard repair (e.g., involving fusing of any units in the memory), signal 318 indicating any in-system and on-chip memory repair that occurred (e.g., during operation of a vehicle) after the hard repair. If, for example, the soft repair enable is toggled off, the multiplexer 312 may, in some embodiments, relay just the signal 315 to the memory 150.

The memory 150, after receiving one or both of the signal 316 and signal 318 and may update a record of repairs 330 based on signal 316 indicating any hard repairs performed via fusing and signal 318 indicating any in-system and on-chip repairs performed during operation of the vehicle based on techniques described herein. In some embodiments, the record of repairs 330 may include a listing of repaired units (e.g., FCL and FCEN) that were fused.

The example hardware and software components may further include the memory controller 180, which may also be referred to herein as “memory wrapper” 180 to distinguish from the memory controller 130. As previously discussed in relation to FIG. 2, the memory controller 180 may include data registers configured to store data in transit between the host 110 and the memory 150, store configuration settings or other data, and provide or receive data via channel 190. The registers may include an internal built-in redundancy analysis (BIRA) register 326 (e.g., for storing memory redundancy information), and a memory reconfiguration (MRR) register 328. Furthermore, the memory controller 180 may include modules configured to perform various functions described herein, such as but not limited to a data comparator 320 configured to compare data stored in memory 150 (e.g., to a correct data according to a memory function test), and a BIRA module 322 configured to conduct the built-in redundancy analysis (BIRA) (e.g., by determining whether a unit of the memory 150 is repairable).

In some embodiments, the in-system and on chip memory repair may include executing a memory built-in self test (MBIST) by the processor 120. The MBIST procedure may include performing a memory function test for a plurality of units of the memory 150. The data comparator 320 may be configured to compare a data stored in a given unit of the memory to a correct data that should be stored (e.g., a correct bit) based on the memory function test, to indicate a memory function status for the unit that is one of a pass or a failure (“fail”). If the memory function test indicates that one or more units of the memory fails the memory function test, the built in redundancy analysis (BIRA) logic 322 may generate one or more values indicating that a repair may need to be done to the one or more failing units. In some embodiments, the BIRA module 322 may further indicate whether a unit for which is repair is needed is repairable or not repairable. For example, the APB Reg control 306 may cause the processor 120 to generate a test pattern (BIRA pattern) to determine whether each of one or more defective units of the memory are repairable or non-repairable. The BIRA module 322 may interpret the results of the pattern and indicate that in the signal 340 provided to the multiplexer 324.

In at least one embodiment, the memory controller 180 may include a multiplexer 324 configured to receive a signal 338 that is output from the multiplexer 312 and a signal 340 that is output from the BIRA module 322. While signal 338 may indicate any hard repairs already performed and any in-system and on-chip performed, signal 340 may indicate if any units(s) of the memory is still in need of repair. For example, 340 may indicate if any unit(s) of the memory are in need of repair and which may not have been addressed by the hard repair indicated by signal 316 and soft repair indicated by signal 318.

As previously discussed, prior to operating the MBIST on the memory 150, the host 110 may initialize the INBR load 310 based on known memory functions for units of the memory 150 based on the hard repair history 302 (e.g., values indicating which units of the memory 150 were hard repaired, as determined from the FPROM of the memory 150). For example, if a unit previously underwent a hard repair at the manufacturing stage by fusing the unit, the indication of such repair and/or fusing of the unit may be indicated in the INBR load 310.

The multiplexer 324 may facilitate the entry of the INBR load 310 into the INBR 326 while updating the INBR 326 to also reflect information from signals 338 and 340. For example, based on signals 338 and 340 provided to the multiplexer 324, INBR 326 may not also store, in addition to previous hard repair information, a most recent soft repair information (e.g., of the most recent clock cycle) for any units of the memory that has undergone an in-system and off-chip memory repair.

In some embodiments, the INBR 126 may be used to further update a memory reconfiguration register (MRR) 328 to indicate which units of the memory were repaired, including based on the hard repair and the soft repair.

The memory controller 180 may thus provide an input signal 318 based on the MRR 328 to the multiplexer 312, to indicate information from the MRR 328 that includes the soft repair information performed as of the most recent clock cycle. The aforementioned processes may be repeated with each clock cycle, to ensure that hard repair information is taken into account (e.g., by determining the hard repair information via an FPROM, encoding the hard repair information into the INBR 326 via INBR load 310), MBIST is run to determine whether any units are defective, and a soft repair is performed and accounted for (e.g., via soft repair control 304, multiplexer 312, data comparator 320, BIRA 322, multiplexer 324, INBR 326 and MRR 328).

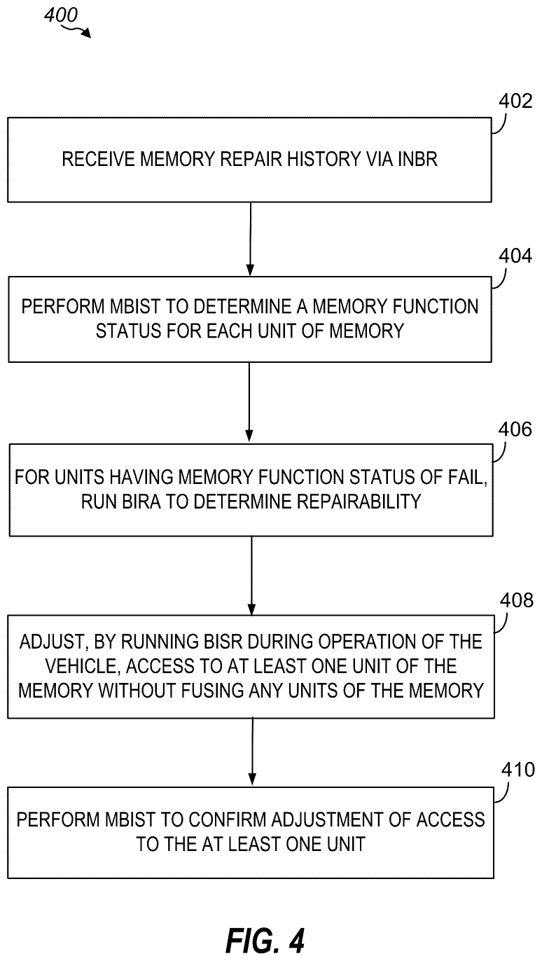

FIG. 4 shows a flow diagram of another example process for the in-system and on-chip memory repair in the automotive embedded system according to one or more aspects of the disclosure. One or more blocks of example process 400 may be performed by at least one processor (e.g., processor 120) in conjunction with one or more components of FIGS. 1-3. Also or alternatively, one or more blocks of example process 400 may be performed by at least one memory controller (e.g., memory controller 130, memory controller 180).

At block 402, the at least one processor or memory controller may receive a memory repair history, via an internal built-in redundancy analysis register (INBR) (e.g., INBR 326). For example, the processor 120 may determine the hard repair history of a memory based on fuse bits of an FPROM of the memory 150. The processor 120 may compile the hard repair history into the INBR load 310 indicating, for each unit of the memory, whether a hard repair may have occurred. The INBR load 310 may be received by the memory controller 180 to enter into the INBR 326.

At block 404, the at least one processor or memory controller may perform a memory built-in self test (MBIST) to determine a memory function status for each unit of the memory. In some embodiments, the memory function status may be determined via a memory function test, in which the result of the test may be a pass or a failure. For example, the processor 120 may utilize the APB Reg control 306 and/or the TCSR control 308 to apply a test pattern as a stimulus to test the memory function of each of a plurality of units 332 (e.g., cells, bits, etc.) of the memory 150. The test may determine which units of the plurality of units 332 are defective units 334 based on the memory function status of failing the test. In some embodiments, the results of the test may be determined via the data comparator 320 of the memory controller 180. For example, after applying the memory function test, the data comparator 320 may compare (e.g., by reading) a data stored in a given unit of the memory (e.g., stored bit) to a correct data that should be stored (e.g., a correct bit) based on the memory function test, to indicate whether memory function status for the unit that is one of a pass or a failure (“fail”).

At block 406, for units having the memory function status of “fail,” the at least one processor or memory controller may perform a built-in redundancy analysis to determine repairability (e.g., whether each of the said units are repairable or non-repairable). For example, the BIRA module 322 may indicate whether a unit for which is repair is needed (e.g., due to failing the memory function test) is repairable or not repairable. In some embodiments, the repairability may be determined by way of implementing a redundancy test pattern implemented by the APB Reg control 306 to determine whether each of one or more defective units of the memory are repairable or non-repairable. The BIRA module 322 may interpret the results of the test and indicate (e.g., in the signal 340 provided to the multiplexer 324 of the memory controller 180) whether a defective unit is repairable or non-repairable. For example, it is possible that a specific defective unit no longer has a corresponding redundant unit, as the defective unit may replaced a prior defective unit that was fused during a hard repair. In such scenario, the specific defective unit may be found to be non-repairable. In some embodiments, the repairability may depend on whether a soft repair can be performed (e.g., if access to the defective unit can be adjusted based on machine readable commands). For example, as previously discussed, a soft repair is distinguishable from a hard repair as the soft repair does not sever (e.g., fuse) connections to the defective unit but merely adjusts access to the defective unit based on executable commands. It is contemplated that, in some embodiments, a defective unit may be situated in an area of the memory where such access may not be adjustable, thus rendering the defective unit as not repairable.

At block 408, the at least one processor or memory controller may adjust access to at least unit of the memory without fusing any units of the memory. The at least one unit of the memory may be a unit that is defective (e.g., due to having a memory function status of ‘fail’ at block 404) and is determined to be repairable (e.g., at block 406). In some embodiments, the adjustment may be performed as part of a built-in self repair (BISR) operation. Furthermore, the soft repair control 304 may be enabled (e.g., by toggling to “on”), allowing the multiplexer 312 to receive information of the adjustment. The adjustment may be performed during the operation of the vehicle. Thus, the adjustment can “patch-up” defective memory while the vehicle is in motion. This is particularly useful as a “hard” repair (e.g., physically fusing the defective unit) may not necessarily be available as an option (e.g., due to memory fuse bit slots being unavailable) or may not necessarily be readily accessible (e.g., due to the vehicle being far from a maintenance location.

At block 410, the at least one processor or memory controller may perform MBIST to confirm the adjustment of the access to the at least one unit (e.g., to ensure completion of the in-system and on-chip memory repair). For example, the processor 120 may again utilize the APB Reg control 306 and/or the TCSR control 308 to apply a test pattern as a stimulus to test the memory function of each of a plurality of units 332, including the at least one unit for which access was adjusted. In some embodiments, the adjustment of the access may include denying commands to read and/or write to a location of the at least one unit and/or divert the commands to a location of at least one corresponding unit. The corresponding unit may be non-defective and can thus yield a ‘pass’ result for the memory function test. In some embodiments, the completion of the adjustment may be recorded in the INBR 326 and MRR 328, and memory 150 (e.g., via multiplexers 324 and 312). The recording may include noting redundancy information (e.g., if access is now granted to a redundant unit of the memory in place of the defective unit) into the INBR 326 and MRR 328.

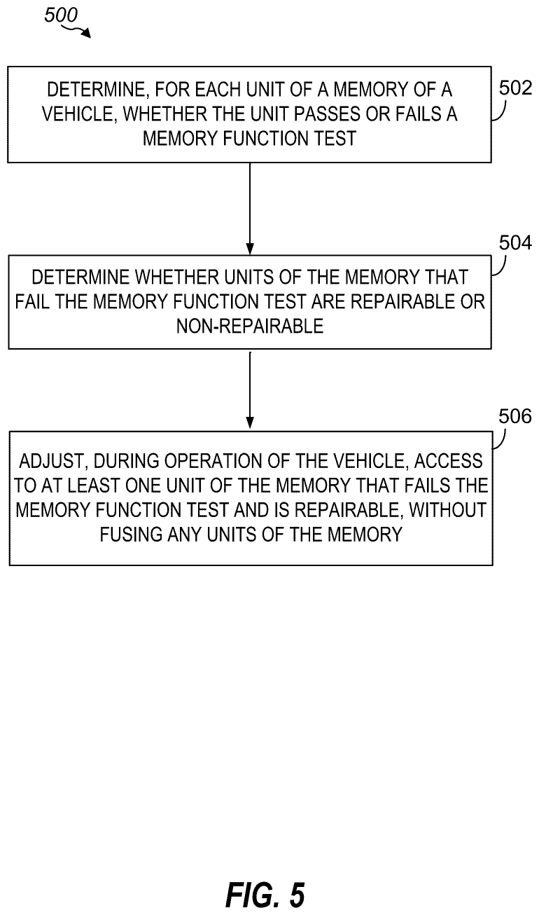

FIG. 5 shows a flow diagram of an example process 500 for the in-system and on-chip memory repair in the automotive embedded system according to one or more aspects of the disclosure. One or more blocks of example process 500 may be performed by at least one processor (e.g., processor 120) in conjunction with one or more components of FIGS. 1-3. Also or alternatively, one or more blocks of example process 500 may be performed by at least one memory controller (e.g., memory controller 130, memory controller 180).

At block 502, the at least one processor or memory controller may determine, for each unit of a memory of a vehicle, whether the unit passes or fails a memory function test. For example, the at least one processor or memory controller may determine a memory built-in self test (MBIST) vector indicating a memory function status for each unit of the memory. The memory function status may indicate whether the unit passes or fails the memory function test. As previously discussed, the memory (e.g., memory 150) may include a memory array 175 of a plurality of units (e.g., cells, bits, columns, rows, etc.) For example, each unit of the memory can be a column of the memory that is accessible to the processor during the operation of the vehicle, at least prior to adjusting any access to a unit, as will be described further in process 500.

At block 504, the at least one processor or memory controller may determine whether units of the memory that fail the memory function test are repairable or non-repairable. In some embodiments, this repairability analysis may be determined by determining a built in redundancy analysis (BIRA) vector indicating whether one or more units of the memory that fail the memory function test are repairable or non-repairable.

At block 506, the at least one processor or memory controller may adjust, during an operation of the vehicle, access to at least one unit of the memory that fails the memory function test and is repairable, without fusing any units of the memory. In some embodiments, the adjustment may be performed by enabling a built-in self repair (BISR) vector to adjust the access to the at least one unit of the memory without fusing any units of the memory. Furthermore, redundancy information associated with the at least one unit may be transferred to a memory reconfiguration register (MRR) after adjusting the access to the at least one unit. In some embodiments, adjusting the access to a defective unit may be distinguishable from a hard repair as the connection to the defective unit is not physically severed. In some embodiments, the adjustment may include denying commands to read or write in the location of the memory corresponding to the defective unit and/or by diverting the commands to read or write, such that the read or write operations are performed in a location of a corresponding redundant unit.

In some embodiments, the method may further include confirming that the access to the at least one unit of the memory is successfully adjusted. For example, this confirmation may include running the MBIST operation again (e.g., by determining the MBIST vector to determine the memory function status for each unit of the memory, after the adjustment of the access of the at least one unit has occurred).

In some embodiments, the in-system and on-chip memory repair based on adjusting the access may update a register tracking hard and soft repairs performed on the memory. For example, in some embodiments, prior to determining whether the unit passes or fails the memory function test, the at least one processor or memory controller may receive a memory repair history via a memory redundancy register. The memory repair history may include an indication of any hard repairs done to any units of the memory (e.g., by fusing). For example, the memory redundancy register may be or may include the internal built-in redundancy analysis register (INBR) 326. The at least one processor or memory controller may update the memory redundancy register after adjusting the access to the at least one unit. In some embodiments, updating the INBR 326 may also include updating the results of determining whether one or more units of the memory that fail the memory function test are repairable or non-repairable.

An automotive embedded system or other vehicle system or device may include a memory system as illustrated in at least FIGS. 1-3 and configured to receive and output data from the memory array and perform an in-system and on-chip repair on the memory array (e.g., during operation of the vehicle). The memory system according to any of the aspects disclosed herein, may be provided in or integrated into any processor-based device. In some embodiments, applications of the in-system and on-chip memory repair can be implemented in other safety critical use cases in addition to or as an alternative to automotive embedded systems, such as but not limited to servers, medical devices, hospital systems, wireless communication devices, or avionics systems.

In one or more aspects, techniques for memory storage and retrieval may include additional aspects, such as any single aspect or any combination of aspects described below or in connection with one or more other processes or devices described elsewhere herein. In a first aspect, an apparatus is disclosed that is configured for in-field memory repair. The apparatus may include a memory of a vehicle storing processor-readable code; and one or more processors coupled to the memory. The one or more processors may be configured to execute the processor-readable code to cause the one or more processors to: determine, for a memory of a vehicle, whether units of the memory fail a memory function test; determine whether one or more units of the memory that fail the memory function test are repairable; and adjust, during operation of the vehicle, access to at least one unit of the memory that fails the memory function test and is repairable.

Additionally, the apparatus may perform or operate according to one or more aspects as described below. In some implementations, the apparatus includes a wireless device, such as a UE. In some implementations, the apparatus includes a remote server, such as a cloud-based computing solution, which receives image data for processing to determine output image frames. In some implementations, the apparatus may include at least one processor, and a memory coupled to the processor. The processor may be configured to perform operations described herein with respect to the apparatus. In some other implementations, the apparatus may include a non-transitory computer-readable medium having program code recorded thereon and the program code may be executable by a computer for causing the computer to perform operations described herein with reference to the apparatus. In some implementations, the apparatus may include one or more means configured to perform operations described herein. In some implementations, a method of wireless communication may include one or more operations described herein with reference to the apparatus.

In a second aspect, in combination with the first aspect, the one or more processors are further configured to: prior to determining whether the one or more units fails the memory function test, receive a memory repair history via a memory redundancy register of the memory; and, after adjusting the access to the at least one unit, update the memory redundancy register.

In a third aspect, in combination with one or more of the first aspect or the second aspect, the memory redundancy register includes an internal built-in redundancy analysis register (INBR). Furthermore, the one or more processors are configured to determine whether one or more units of the memory that fail the memory function test are repairable by updating the INBR based on determining the at least one unit of the memory that fails the memory function test and is repairable.

In a fourth aspect, in combination with one or more of the first aspect through the third aspect, the one or more processors are further configured to: confirm that access to the at least one unit of the memory is successfully adjusted.

In a fifth aspect, in combination with one or more of the first aspect through the fourth aspect, the one or more processors are configured to determine whether the unit fails the memory function test by: determining a memory built-in self test (MBIST) vector indicating a memory function status for each unit of the memory. The memory function status indicates whether the unit fails the memory function test. Furthermore, the one or more processors are configured to confirm that the access to the at least one unit of the memory is successfully adjusted based on the MBIST vector.

In a sixth aspect, in combination with one or more of the first aspect through the fifth aspect, the one or more processors are configured to determine whether one or more units of the memory that fail the memory function test are repairable or non-repairable by: determining a built in redundancy analysis (BIRA) vector indicating whether one or more units of the memory that fail the memory function test are repairable.

In a seventh aspect, in combination with one or more of the first aspect through the sixth aspect, the one or more processors are configured to repair the at least one unit of the memory by: enabling a built-in self repair (BISR) vector to adjust the access to the at least one unit of the memory without fusing any units of the memory; and transferring redundancy information associated with the at least one unit to a memory reconfiguration register (MRR) after adjusting the access to the at least one unit.

In an eighth aspect, in combination with one or more of the first aspect through the seventh aspect, each unit of the memory is a column of the memory that is accessible to the one or more processors during the operation of the vehicle prior to adjusting the access to the at least one unit.

In a ninth aspect, a method for in-field memory repair in a vehicle is disclosed. The method may include: determining, by a processor for a memory of a vehicle, whether units of the memory fail a memory function test; determining, by the processor, whether one or more units of the memory that fail the memory function test are repairable; and adjusting, by the processor and during operation of the vehicle, access to at least one unit of the memory that fails the memory function test and is repairable.

In a tenth aspect, in combination with the ninth aspect, the method further includes: prior to determining whether one or more units fails the memory function test, receiving, by the processor, a memory repair history based on a memory redundancy register of the memory; and, after adjusting the access to the at least one unit, updating, by the processor, the memory redundancy register.

In an eleventh aspect, in combination with one or more of the ninth aspect through the tenth aspect, the memory redundancy register includes an internal built-in redundancy analysis register (INBR). Furthermore, determining whether one or more units of the memory that fail the memory function test are repairable includes updating the INBR based on determining the at least one unit of the memory that fails the memory function test and is repairable.

In a twelfth aspect, in combination with one or more of the ninth aspect through the eleventh aspect, the method further includes: confirming, by the processor, that access to the at least one unit of the memory is successfully adjusted.

In a thirteenth aspect, in combination with one or more of the ninth aspect through the twelfth aspect, determining whether the unit fails the memory function test includes: determining a memory built-in self test (MBIST) vector indicating a memory function status for each unit of the memory. The memory function status may indicate whether the unit passes or fails the memory function test. Furthermore, confirming that the access to the at least one unit of the memory is successfully adjusted may be based on the MBIST vector.

In a fourteenth aspect, in combination with one or more of the ninth aspect through the thirteenth aspect, determining whether one or more units of the memory that fail the memory function test are repairable includes: determining a built in redundancy analysis (BIRA) vector indicating whether one or more units of the memory that fail the memory function test are repairable.

In a fifteenth aspect, in combination with one or more of the ninth aspect through the fourteenth aspect, adjusting the access to the at least one unit of the memory includes: enabling, by the processor, a built-in self repair (BISR) vector to adjust the access to the at least one unit of the memory without fusing any units of the memory; and transferring redundancy information associated with the at least one unit to a memory reconfiguration register (MRR) after adjusting the access to the at least one unit.

In a sixteenth aspect, in combination with one or more of the ninth aspect through the fifteenth aspect, each unit of the memory is a column of the memory that is accessible to the processor during the operation of the vehicle prior to adjusting the access to the at least one unit.

In a seventeenth aspect, a system for an in-field memory repair in a vehicle is disclosed. The system may include: a memory of the vehicle, where the memory includes a plurality of units and stores processor-readable code; and at least one processor coupled to the memory. the at least one processor is configured to execute the processor-readable code to cause the at least one processor to perform operations including: determining, for each unit of the memory via a memory built-in self test (MBIST) vector, whether the unit fails a memory function test; determining, via a built-in redundancy analysis (BIRA) vector, based on a memory repair history of the memory, whether one or more units of the memory that fail the memory function test are repairable; adjusting, by enabling a built-in self repair (BISR) vector, access to at least one unit of the memory that fails the memory function test and is repairable without fusing any units of the memory; and confirming, via the MBIST vector, that the access to the at least one unit of the memory is successfully adjusted.

In an eighteenth aspect, in combination with the seventeenth aspect, the at least one processor is configured to perform operations further including: prior to determining whether the unit fails the memory function test, receiving, by the processor, the memory repair history of the memory via an internal built-in redundancy analysis register (INBR); and after adjusting the access to the at least one unit, updating the INBR.

In a nineteenth aspect, in combination with one or more of the seventeenth aspect through the eighteenth aspect, the at least one processor is configured to perform operations further including: transferring redundancy information associated with the at least one unit to a memory reconfiguration register (MRR) after adjusting the access to the at least one unit.

In a twentieth aspect, in combination with one or more of the seventeenth aspect through the nineteenth aspect, the at least one processor is configured to repair the at least one unit of the memory after the operation of the vehicle.

In the description of embodiments herein, numerous specific details are set forth, such as examples of specific components, circuits, and processes to provide a thorough understanding of the present disclosure. The term “coupled” as used herein means connected directly to or connected through one or more intervening components or circuits. Also, in the following description and for purposes of explanation, specific nomenclature is set forth to provide a thorough understanding of the present disclosure. However, it will be apparent to one skilled in the art that these specific details may not be required to practice the teachings disclosed herein. In other instances, well known circuits and devices are shown in block diagram form to avoid obscuring teachings of the present disclosure.

Some portions of the detailed descriptions which follow are presented in terms of procedures, logic blocks, processing, and other symbolic representations of operations on data bits within a computer memory. In the present disclosure, a procedure, logic block, process, or the like, is conceived to be a self-consistent sequence of steps or instructions leading to a desired result. The steps are those requiring physical manipulations of physical quantities. Usually, although not necessarily, these quantities take the form of electrical or magnetic signals capable of being stored, transferred, combined, compared, and otherwise manipulated in a computer system.

In the figures, a single block may be described as performing a function or functions. The function or functions performed by that block may be performed in a single component or across multiple components, and/or may be performed using hardware, software, or a combination of hardware and software. To clearly illustrate this interchangeability of hardware and software, various illustrative components, blocks, modules, circuits, and steps are described below generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure. Also, the example devices may include components other than those shown, including well-known components such as a processor, memory, and the like.

Unless specifically stated otherwise as apparent from the following discussions, it is appreciated that throughout the present application, discussions utilizing the terms such as “accessing,” “receiving,” “sending,” “using,” “selecting,” “determining,” “normalizing,” “multiplying,” “averaging,” “monitoring,” “comparing,” “applying,” “updating,” “measuring,” “deriving,” “settling,” “generating,” or the like, refer to the actions and processes of a computer system, or similar electronic computing device, that manipulates and transforms data represented as physical (electronic) quantities within the computer system's registers and memories into other data similarly represented as physical quantities within the computer system's registers, memories, or other such information storage, transmission, or display devices.

The terms “device” and “apparatus” are not limited to one or a specific number of physical objects (such as one smartphone, one camera controller, one processing system, and so on). As used herein, a device may be any electronic device with one or more parts that may implement at least some portions of the disclosure. While the description and examples herein use the term “device” to describe various aspects of the disclosure, the term “device” is not limited to a specific configuration, type, or number of objects. As used herein, an apparatus may include a device or a portion of the device for performing the described operations.

Certain components in a device or apparatus described as “means for accessing,” “means for receiving,” “means for sending,” “means for using,” “means for selecting,” “means for determining,” “means for normalizing,” “means for multiplying,” or other similarly-named terms referring to one or more operations on data, such as image data, may refer to processing circuitry (e.g., application specific integrated circuits (ASICs), digital signal processors (DSP), graphics processing unit (GPU), central processing unit (CPU)) configured to perform the recited function through hardware, software, or a combination of hardware configured by software.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Components, the functional blocks, and the modules described herein with respect to FIGS. 1-3 include processors, electronics devices, hardware devices, electronics components, logical circuits, memories, software codes, firmware codes, among other examples, or any combination thereof. Software shall be construed broadly to mean instructions, instruction sets, code, code segments, program code, programs, subprograms, software modules, application, software applications, software packages, routines, subroutines, objects, executables, threads of execution, procedures, and/or functions, among other examples, whether referred to as software, firmware, middleware, microcode, hardware description language or otherwise. In addition, features discussed herein may be implemented via specialized processor circuitry, via executable instructions, or combinations thereof.

Those of skill in the art that one or more blocks (or operations) described with reference to the figures included with this description may be combined with one or more blocks (or operations) described with reference to another of the figures. For example, one or more blocks (or operations) of FIG. 3 may be combined with one or more blocks (or operations) of FIG. 1 or FIG. 2.

Those of skill in the art would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure. Skilled artisans will also readily recognize that the order or combination of components, methods, or interactions that are described herein are merely examples and that the components, methods, or interactions of the various aspects of the present disclosure may be combined or performed in ways other than those illustrated and described herein.

The various illustrative logics, logical blocks, modules, circuits and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits, and processes described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single-or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, or any conventional processor, controller, microcontroller, or state machine. In some implementations, a processor may be implemented as a combination of computing devices, such as a combination of a DSP and a microprocessor, a plurality of microprocessors, one or more microprocessors in conjunction with a DSP core, or any other such configuration. In some implementations, particular processes and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also may be implemented as one or more computer programs, which is one or more modules of computer program instructions, encoded on a computer storage media for execution by, or to control the operation of, data processing apparatus.

If implemented in software, the functions may be stored on or transmitted over as one or more instructions or code on a computer-readable medium. The processes of a method or algorithm disclosed herein may be implemented in a processor-executable software module which may reside on a computer-readable medium. Computer-readable media includes both computer storage media and communication media including any medium that may be enabled to transfer a computer program from one place to another. A storage media may be any available media that may be accessed by a computer. By way of example, and not limitation, such computer-readable media may include random-access memory (RAM), read-only memory (ROM), electrically erasable programmable read-only memory (EEPROM), CD-ROM or other optical disk storage, magnetic disk storage or other magnetic storage devices, or any other medium that may be used to store desired program code in the form of instructions or data structures and that may be accessed by a computer. Also, any connection may be properly termed a computer-readable medium. Disk and disc, as used herein, includes compact disc (CD), laser disc, optical disc, digital versatile disc (DVD), floppy disk, and Blu-ray disc where disks usually reproduce data magnetically, while discs reproduce data optically with lasers. Combinations of the above should also be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to some other implementations without departing from the spirit or scope of this disclosure. Thus, the claims are not intended to be limited to the implementations shown herein but are to be accorded the widest scope consistent with this disclosure, the principles and the novel features disclosed herein.

Additionally, a person having ordinary skill in the art will readily appreciate, opposing terms such as “upper” and “lower,” or “front” and back,” or “top” and “bottom,” or “forward” and “backward” are sometimes used for ease of describing the figures, and indicate relative positions corresponding to the orientation of the figure on a properly oriented page, and may not reflect the proper orientation of any device as implemented.

As used herein, the term “coupled to” in the various tenses of the verb “couple” may mean that element A is directly connected to element B or that other elements may be connected between elements A and B (i.e., that element A is indirectly connected with element B), to operate certain intended functions. In the case of electrical components, the term “coupled to” may also be used herein to mean that a wire, trace, or other electrically conductive material is used to electrically connect elements A and B (and any components electrically connected therebetween). In some examples, the term “coupled to” mean a transfer of electrical energy between elements A and B, to operate certain intended functions.

In some examples, the term “electrically connected” mean having an electric current or configurable to having an electric current flowing between the elements A and B. For example, the elements A and B may be connected via resistors, transistors, or an inductor, in addition to a wire, trace, or other electrically conductive material and components. Furthermore, for radio frequency functions, the elements A and B may be “electrically connected” via a capacitor.

Certain features that are described in this specification in the context of separate implementations also may be implemented in combination in a single implementation. Conversely, various features that are described in the context of a single implementation also may be implemented in multiple implementations separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown, or in sequential order, or that all illustrated operations be performed to achieve desirable results. Further, the drawings may schematically depict one or more example processes in the form of a flow diagram. However, other operations that are not depicted may be incorporated in the example processes that are schematically illustrated. For example, one or more additional operations may be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems may generally be integrated together in a single software product or packaged into multiple software products. Additionally, some other implementations are within the scope of the following claims. In some cases, the actions recited in the claims may be performed in a different order and still achieve desirable results.

As used herein, including in the claims, the term “or,” when used in a list of two or more items, means that any one of the listed items may be employed by itself, or any combination of two or more of the listed items may be employed. For example, if a composition is described as containing components A, B, or C, the composition may contain A alone; B alone; C alone; A and B in combination; A and C in combination; B and C in combination; or A, B, and C in combination. Also, as used herein, including in the claims, “or” as used in a list of items prefaced by “at least one of” indicates a disjunctive list such that, for example, a list of “at least one of A, B, or C” means A or B or C or AB or AC or BC or ABC (that is A and B and C) or any of these in any combination thereof.

The term “substantially” is defined as largely, but not necessarily wholly, what is specified (and includes what is specified; for example, substantially 90 degrees includes 90 degrees and substantially parallel includes parallel), as understood by a person of ordinary skill in the art. In any disclosed implementations, the term “substantially” may be substituted with “within [a percentage] of” what is specified, where the percentage includes 0.1, 1, 5, or 10 percent.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

What is claimed is:

1. A method, comprising:
determining, by a processor for a memory of a vehicle, whether units of the memory fail a memory function test;
determining, by the processor, whether one or more units of the memory that fail the memory function test are repairable; and
adjusting, by the processor and during operation of the vehicle, access to at least one unit of the memory that fails the memory function test and is repairable.

2. The method of claim 1, further comprising:
prior to determining whether one or more units fails the memory function test, receiving, by the processor, a memory repair history based on a memory redundancy register of the memory; and
after adjusting the access to the at least one unit, updating, by the processor, the memory redundancy register.

3. The method of claim 2,
wherein the memory redundancy register comprises an internal built-in redundancy analysis register (INBR), and
wherein determining whether one or more units of the memory that fail the memory function test are repairable comprises updating the INBR based on determining the at least one unit of the memory that fails the memory function test and is repairable.

4. The method of claim 1, further comprising:
confirming, by the processor, that access to the at least one unit of the memory is successfully adjusted.

5. The method of claim 3, wherein determining whether one or more units of the memory fail the memory function test comprises:
determining a memory built-in self test (MBIST) vector indicating a memory function status for each unit of the memory, wherein the memory function status indicates whether each unit passes or fails the memory function test;
wherein confirming that the access to the at least one unit of the memory is successfully adjusted is based on the MBIST vector.

6. The method of claim 1, wherein determining whether one or more units of the memory that fail the memory function test are repairable comprises:
determining a built in redundancy analysis (BIRA) vector indicating whether one or more units of the memory that fail the memory function test are repairable.

7. The method of claim 1, wherein adjusting the access to the at least one unit of the memory comprises:
enabling, by the processor, a built-in self repair (BISR) vector to adjust the access to the at least one unit of the memory without fusing any units of the memory; and
transferring redundancy information associated with the at least one unit to a memory reconfiguration register (MRR) after adjusting the access to the at least one unit.

8. The method of claim 1, wherein each unit of the memory is a column of the memory that is accessible to the processor during the operation of the vehicle prior to adjusting the access to the at least one unit.

9. An apparatus, comprising:
a memory of a vehicle storing processor-readable code; and
one or more processors coupled to the memory, the one or more processors configured to execute the processor-readable code to cause the one or more processors to:
determine, for the memory of the vehicle, whether units of the memory fail a memory function test;
determine whether one or more units of the memory that fail the memory function test are repairable; and
adjust, during operation of the vehicle, access to at least one unit of the memory that fails the memory function test and is repairable.

10. The apparatus of claim 9, wherein the one or more processors are further configured to:
prior to determining whether the one or more units fails the memory function test, receive a memory repair history via a memory redundancy register of the memory; and
after adjusting the access to the at least one unit, update the memory redundancy register.

11. The apparatus of claim 10,
wherein the memory redundancy register comprises an internal built-in redundancy analysis register (INBR), and
wherein the one or more processors are configured to determine whether one or more units of the memory that fail the memory function test are repairable by updating the INBR based on determining the at least one unit of the memory that fails the memory function test and is repairable.

12. The apparatus of claim 9, wherein the one or more processors are further configured to:
confirm that access to the at least one unit of the memory is successfully adjusted.

13. The apparatus of claim 12, wherein the one or more processors are configured to determine whether the one or more units of the memory fail the memory function test by:
determining a memory built-in self test (MBIST) vector indicating a memory function status for each unit of the memory, wherein the memory function status indicates whether each unit fails the memory function test;
wherein the one or more processors are configured to confirm that the access to the at least one unit of the memory is successfully adjusted based on the MBIST vector.

14. The apparatus of claim 9, wherein the one or more processors are configured to determine whether one or more units of the memory that fail the memory function test are repairable or non-repairable by:
determining a built in redundancy analysis (BIRA) vector indicating whether one or more units of the memory that fail the memory function test are repairable.

15. The apparatus of claim 9, wherein the one or more processors are configured to repair the at least one unit of the memory by:
enabling a built-in self repair (BISR) vector to adjust the access to the at least one unit of the memory without fusing any units of the memory; and
transferring redundancy information associated with the at least one unit to a memory reconfiguration register (MRR) after adjusting the access to the at least one unit.

16. The apparatus of claim 9, wherein each unit of the memory is a column of the memory that is accessible to the one or more processors during the operation of the vehicle prior to adjusting the access to the at least one unit.

17. A system for an in-field memory repair in a vehicle, comprising:
a memory of the vehicle, wherein the memory comprises a plurality of units and stores processor-readable code; and
at least one processor coupled to the memory, wherein the at least one processor is configured to execute the processor-readable code to cause the at least one processor to perform operations comprising:
determining, for each unit of the memory via a memory built-in self test (MBIST) vector, whether each unit fails a memory function test;
determining, via a built-in redundancy analysis (BIRA) vector, based on a memory repair history of the memory, whether one or more units of the memory that fail the memory function test are repairable;
adjusting, by enabling a built-in self repair (BISR) vector, access to at least one unit of the memory that fails the memory function test and is repairable without fusing any units of the memory; and
confirming, via the MBIST vector, that the access to the at least one unit of the memory is successfully adjusted.

18. The system of claim 17, wherein the at least one processor is configured to perform operations further comprising:
prior to determining whether each unit fails the memory function test, receiving, by the processor, the memory repair history of the memory via an internal built-in redundancy analysis register (INBR); and
after adjusting the access to the at least one unit, updating the INBR.

19. The system of claim 17, wherein the at least one processor is configured to perform operations further comprising:
transferring redundancy information associated with the at least one unit to a memory reconfiguration register (MRR) after adjusting the access to the at least one unit.

20. The system of claim 17, wherein the at least one processor is configured to repair the at least one unit of the memory after the operation of the vehicle.
